(19) United States
(12) Patent Application Publication
(10) Pub. No.: US 2024/0355748 A1
(43) Pub. Date: Oct. 24, 2024

(54) HIGH-PERFORMANCE SEMICONDUCTOR FAN OUT PACKAGE

(71) Applicant: Micron Technology, Inc, Boise, ID (US)

(72) Inventors: Chan H. YOO, Boise, ID (US); Christopher GLANCEY, Boise, ID (US); Walter L. MODEN, Boise, ID (US); Travis Michael JENSEN, Boise, ID (US)

(21) Appl. No.: 18/629,224

(22) Filed: Apr. 8, 2024

Related U.S. Application Data
(60) Provisional application No. 63/497,325, filed on Apr. 20, 2023.

(51) Int. Cl. H01L 23/538; H01L 21/56; H01L 23/00; H01L 23/31; H01L 23/498; H01L 25/10

(52) U.S. Cl. CPC H01L 23/5385; H01L 21/56; H01L 23/3107; H01L 23/49816; H01L 24/16; H01L 24/81; H01L 25/105; H01L 2224/16227; H01L 2224/81801

(57) ABSTRACT

Implementations described herein relate to various semiconductor device assemblies. In some implementations, a semiconductor device assembly may include a first fan out redistribution layer, a first semiconductor die disposed on a first side, in a direction, of the first fan out redistribution layer and coupled to a first face of the first fan out redistribution layer, and a second semiconductor die disposed on a second side, in the direction, of the first fan out redistribution layer, different from the first side, and coupled to a second face of the first fan out redistribution layer, different from the first face.

### CROSS-REFERENCE TO RELATED APPLICATION

This patent application claims priority to U.S. Provisional Patent Application No. 63/497,325, filed on Apr. 20, 2023, and entitled “HIGH-PERFORMANCE SEMICONDUCTOR FAN OUT PACKAGE.” The disclosure of the prior application is considered part of and is incorporated by reference into this patent application.

### TECHNICAL FIELD

The present disclosure generally relates to semiconductor devices and methods of forming semiconductor devices. For example, the present disclosure relates to a high-performance semiconductor fan out package.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 is a diagram of an example apparatus associated with integrated circuits.

FIG. 2 is a diagram of an example memory device associated with integrated circuits.

FIG. 3 is a diagram of an example semiconductor fan out package according to some implementations.

FIGS. 4A-4N are diagrams of an example process used to fabricate a semiconductor fan out package.

FIG. 5 is a diagram of example equipment used to manufacture various semiconductor packages, semiconductor dies, memory devices, or similar components described herein.

FIG. 6 is a flowchart of an example method of forming an integrated assembly or memory device having fan out packaging.

### DETAILED DESCRIPTION

Semiconductor device assemblies (sometimes referred to as semiconductor packages) may include multiple semiconductor chips or semiconductor dies (sometimes referred to herein simply as “dies”). For example, a memory device or a similar semiconductor device may be associated with a multichip package (MCP). An MCP may integrally include a controller (e.g., a memory controller, a microcontroller, or a similar controller) and/or multiple semiconductor dies (e.g., memory dies, such as NAND dies, dynamic random access memory (DRAM) dies, or similar dies). In some cases, an MCP may use an organic substrate for supporting a controller and/or multiple semiconductor dies. Moreover, in order to reduce a footprint and/or form factor size associated with an MCP, multiple dies may be arranged vertically, such as in a die stack on the substrate. Each of the dies in a die stack may be electrically coupled to each other and/or the substrate via a plurality of electrical connections. For example, dies in a die stack may be arranged in a shingle shack arrangement, in which die edges may not be aligned in order to provide space for wire bonding near the edges of the dies. Additionally, or alternatively, in some cases, a through silicon via (TSV) (sometimes referred to as a through chip via (TCV)) may be provided in a die stack to provide a vertical electrical connection (e.g., a via) that passes through the die stack to the substrate.

Use of wire bonds, TSVs, or similar electrical connections in an MCP may result in certain drawbacks. For example, in packages including wire bonds, package performance may be relatively poor because wire bonds may be incapable of providing a high quality signal and/or high power delivery necessary for high-speed applications. Moreover, although TSVs may be capable of providing high signal integrity and/or high power delivery necessary for high-speed applications, TSVs may be relatively expensive to manufacture and/or may require a relatively complex manufacturing process, thereby reducing package manufacturing throughput and increasing a fabrication cost.

Some implementations described herein enable manufacturing of a high-performance semiconductor fan out package (FOP), such as a high-performance memory FOP, that provides a high density, small form factor package that may be manufactured with a high package throughput and a relatively low fabrication cost by eliminating the use of wire bonds and/or TSVs. In some implementations, multiple dies (e.g., multiple memory chips) may be electrically coupled to a fan out redistribution layer (RDL) formed either through a wafer-level or a panel-level build up process. Moreover, each chip level in the FOP may be electrically connected through pillars (e.g., copper posts) running through a mold layer of the FOP, with the pillars being plated as part of the RDL process. In such implementations, memory density may be scalable with each vertical level build up process while eliminating the high cost of TSV structures and maintaining a small form factor package (e.g., chip size package). Accordingly, the high performance semiconductor FOP may allow for reduced conductor length compared to conventional manufacturing techniques, such as package on package (POP) techniques, reduced timing delay as compared to conventional MCPs, and/or enhanced signal integrity and power delivery at high-speed applications as compared to conventional MCPs. These and other benefits are described in more detail below in connection with the following figures.

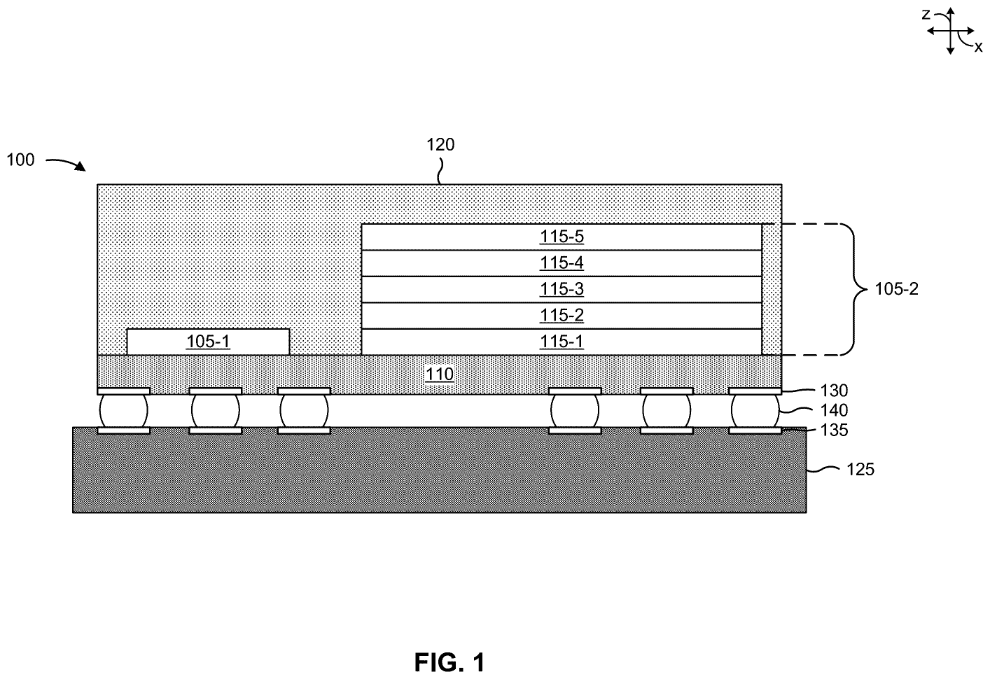

FIG. 1 is a diagram of an example apparatus 100 associated with integrated circuits.

In FIG. 1 and the figures that follow, each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a DRAM device, a static RAM (SRAM) device, a synchronous dynamic RAM (SDRAM) device, a ferroelectric RAM (FeRAM) device, a magnetic RAM (MRAM) device, a resistive RAM (RRAM) device, a holographic RAM (HRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include a single semiconductor die 115 (sometimes called a die), as shown by the first integrated circuit 105-1. In some implementations, an integrated circuit 105 may include multiple semiconductor dies 115 (sometimes called dies), as shown by the second integrated circuit 105-2, which is shown as including five semiconductor dies 115-1 through 115-5.

As shown in FIG. 1, for an integrated circuit 105 that includes multiple dies 115, the dies 115 may be stacked on top of each other to reduce a footprint of the apparatus 100. In some implementations, a spacer may be present between dies 115 that are adjacent to one another in the stack to enable electrical separation and heat dissipation. The stacked dies 115 may include three-dimensional electrical interconnects, such as TSVs, to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on. Although FIG. 1 shows the dies 115 stacked in a straight stack (e.g., with aligned die edges), in some implementations, the dies 115 may be stacked in a different arrangement, such as a shingle stack (e.g., with die edges that are not aligned, which provides space for wire bonding near the edges of the dies 115).

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a mold compound, a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a printed circuit board (PCB). For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system.

As indicated above, FIG. 1 is provided as an example. Other examples may differ from what is described with regard to FIG. 1.

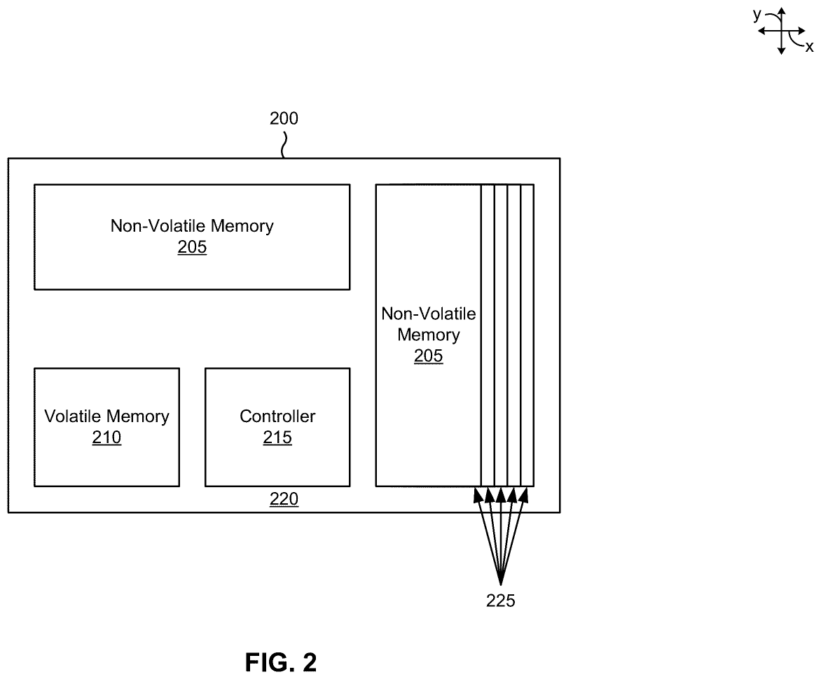

FIG. 2 is a diagram of an example memory device 200 associated with integrated circuits. The memory device 200 is an example of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes a single die. Additionally, or alternatively, the non-volatile memory 205 may include multiple dies, such as stacked semiconductor dies 225 (e.g., in a straight stack, a shingle stack, or another type of stack, which may include one or more TSVs, wire bonds, or similar electrical connections), as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

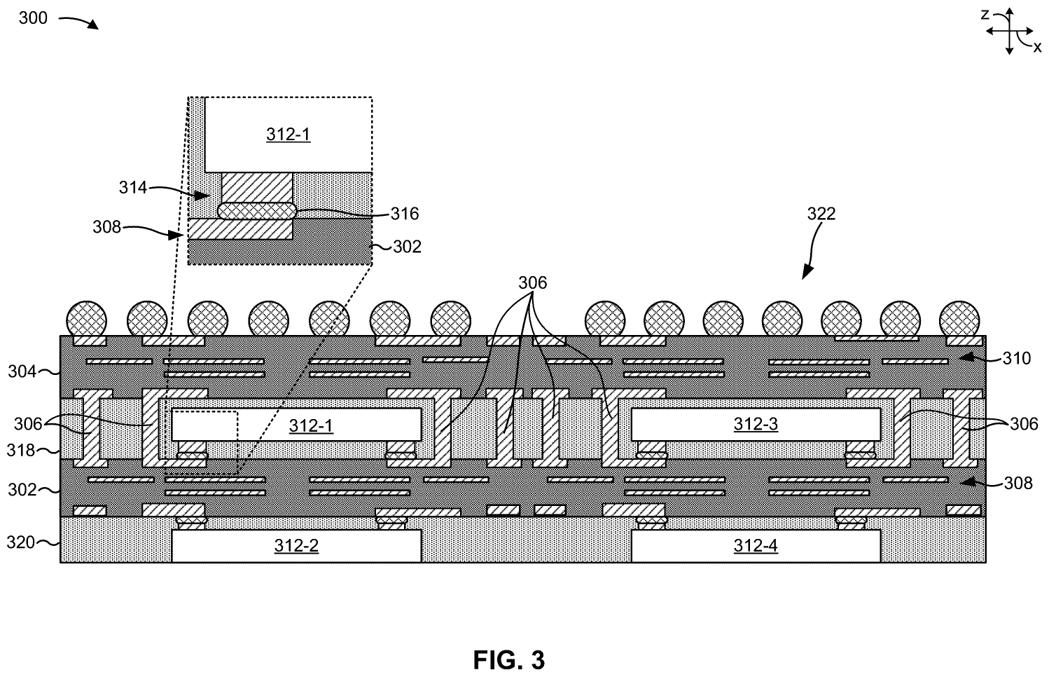

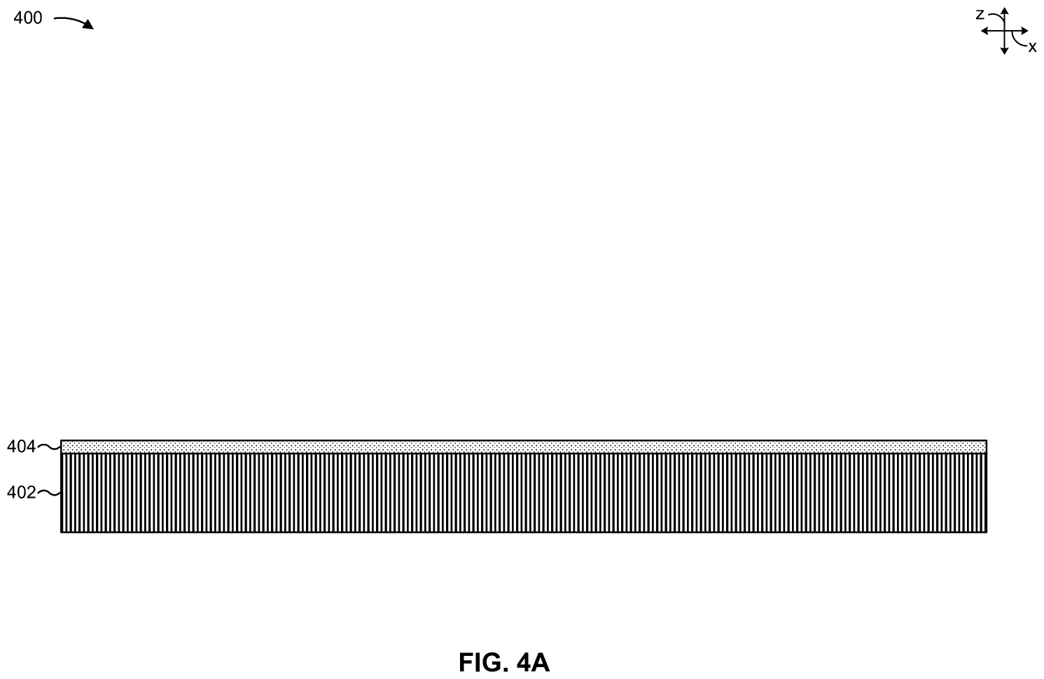

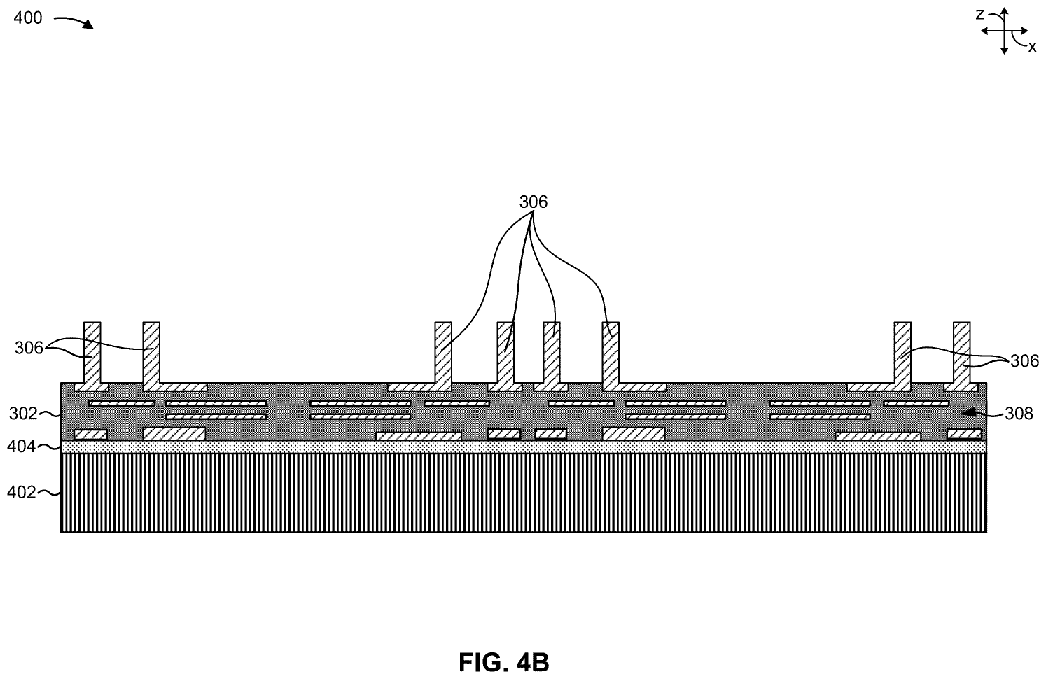

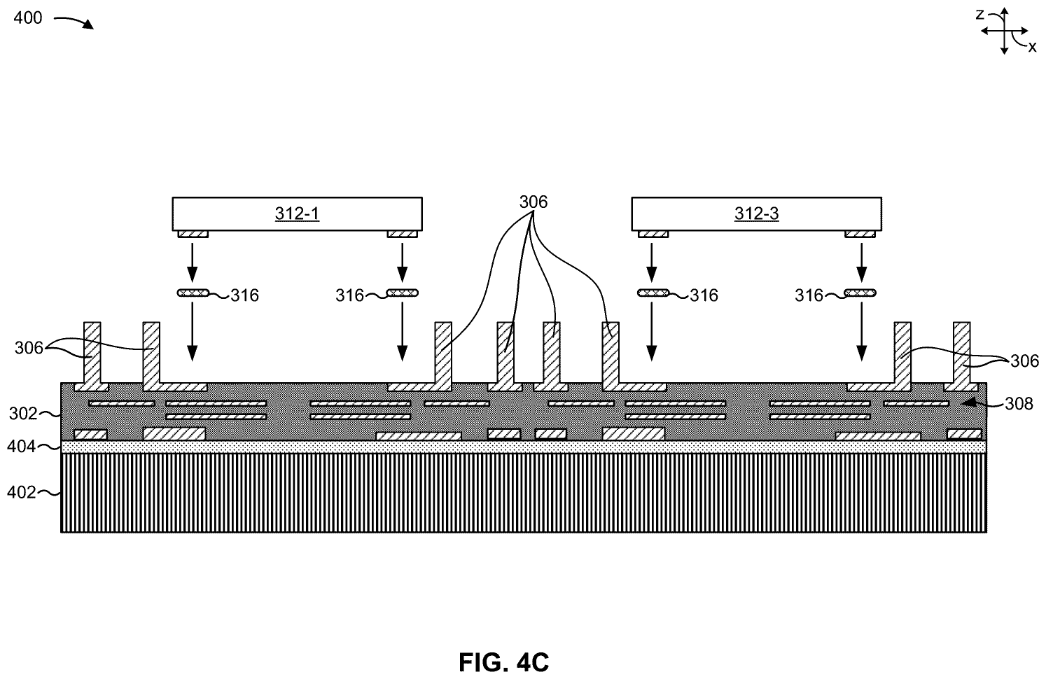

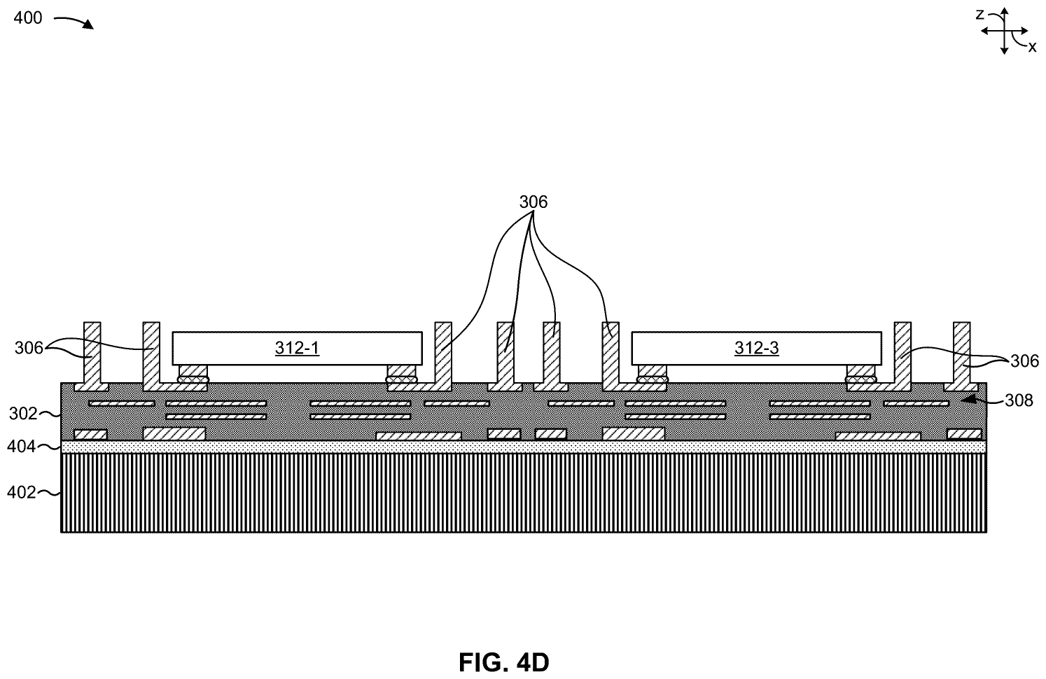

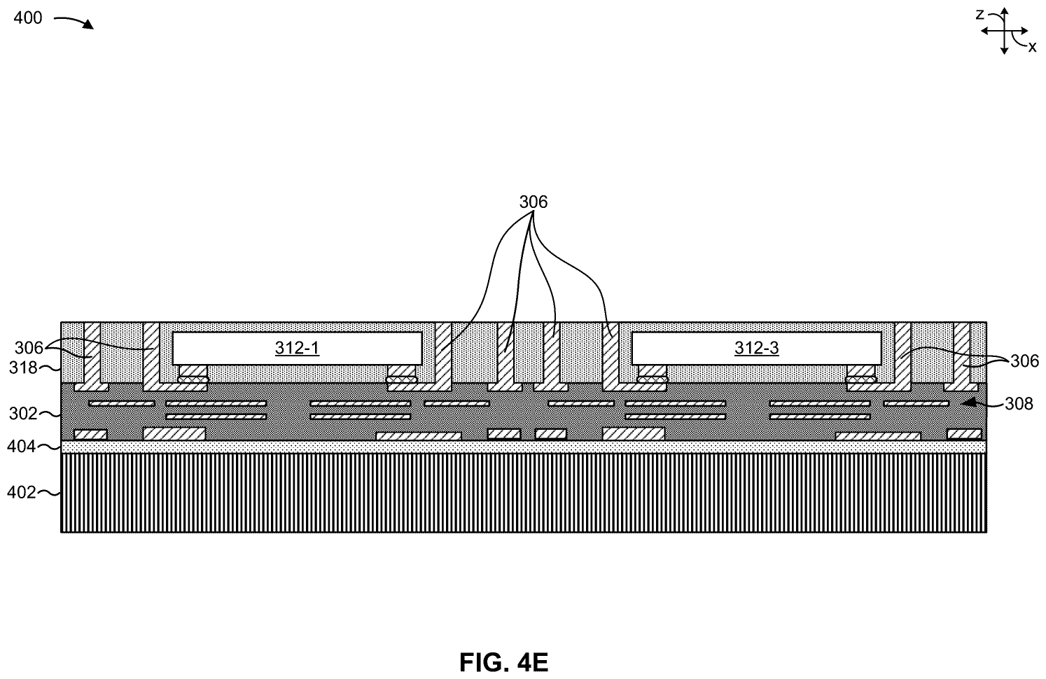

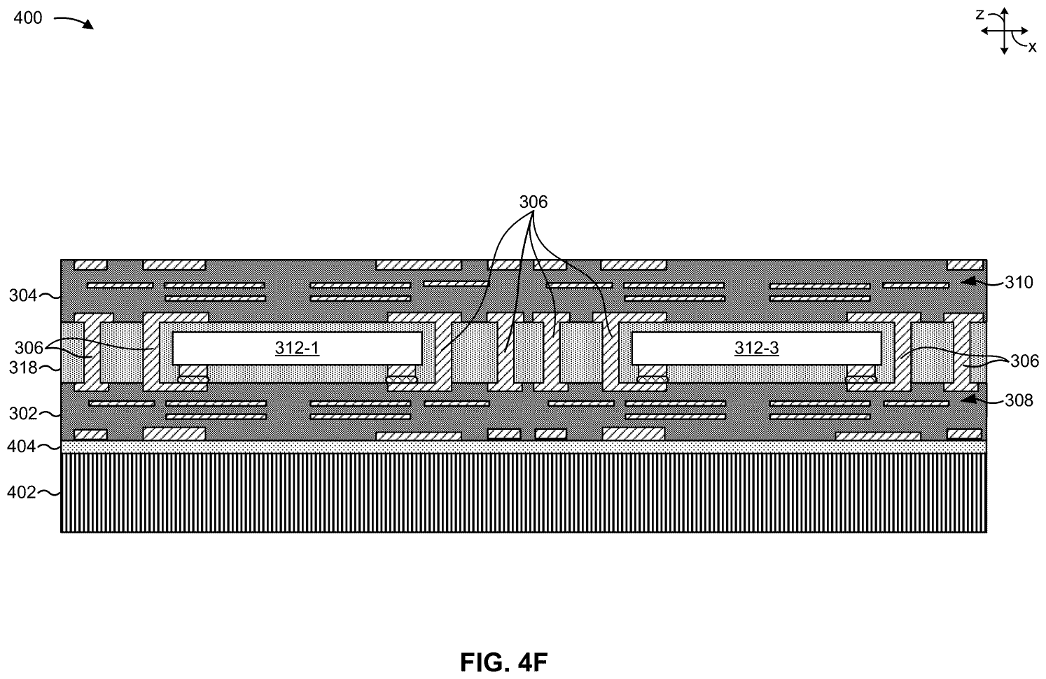

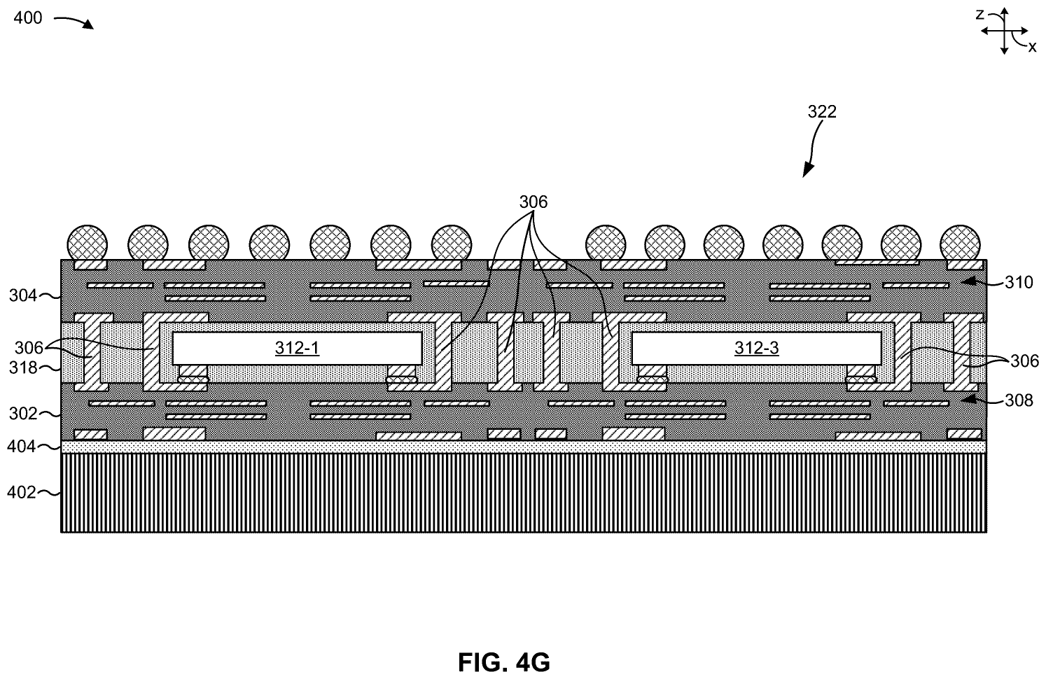

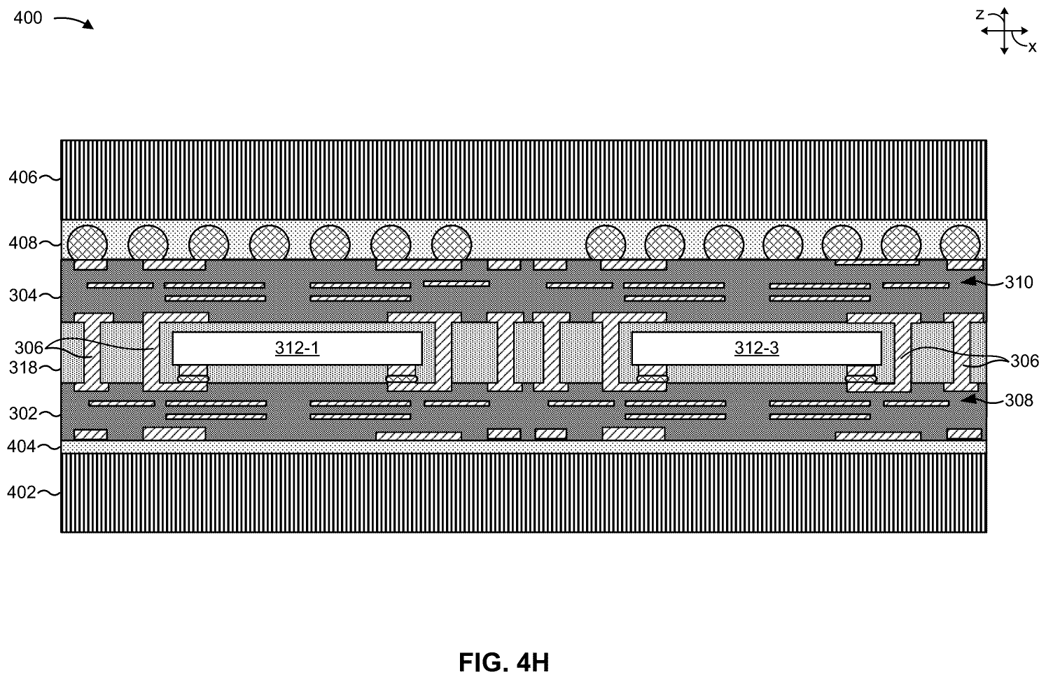

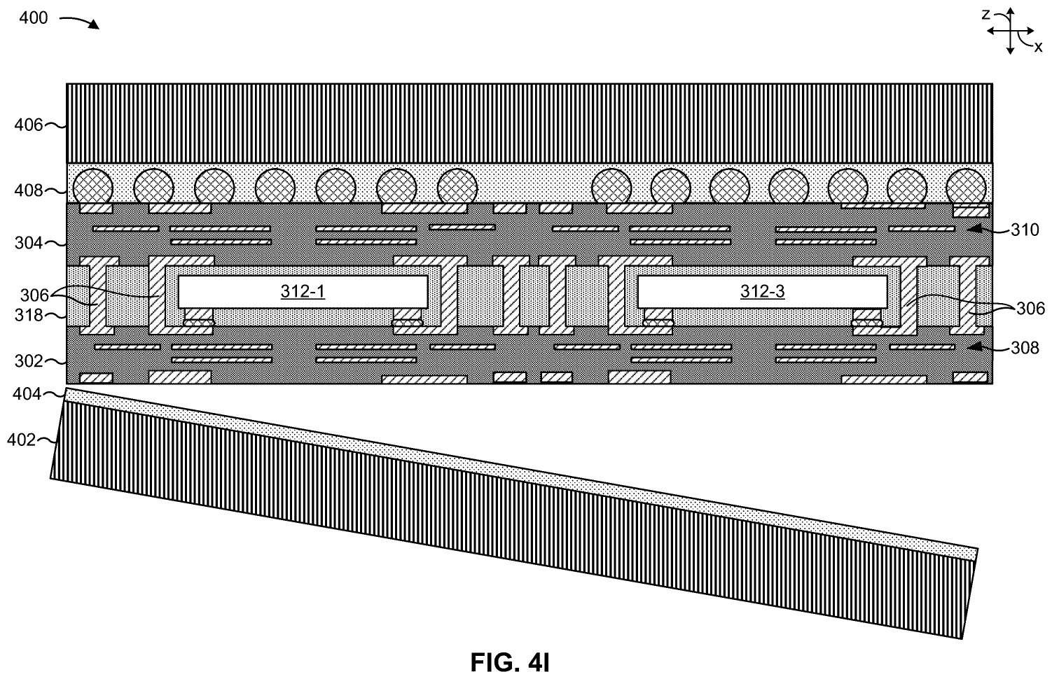

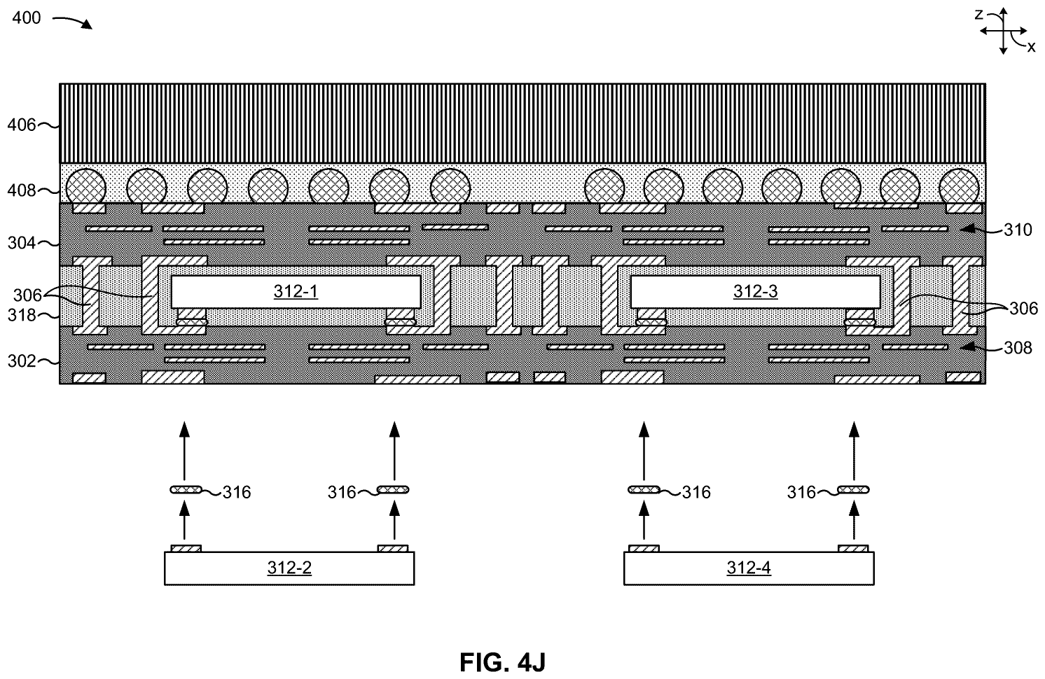

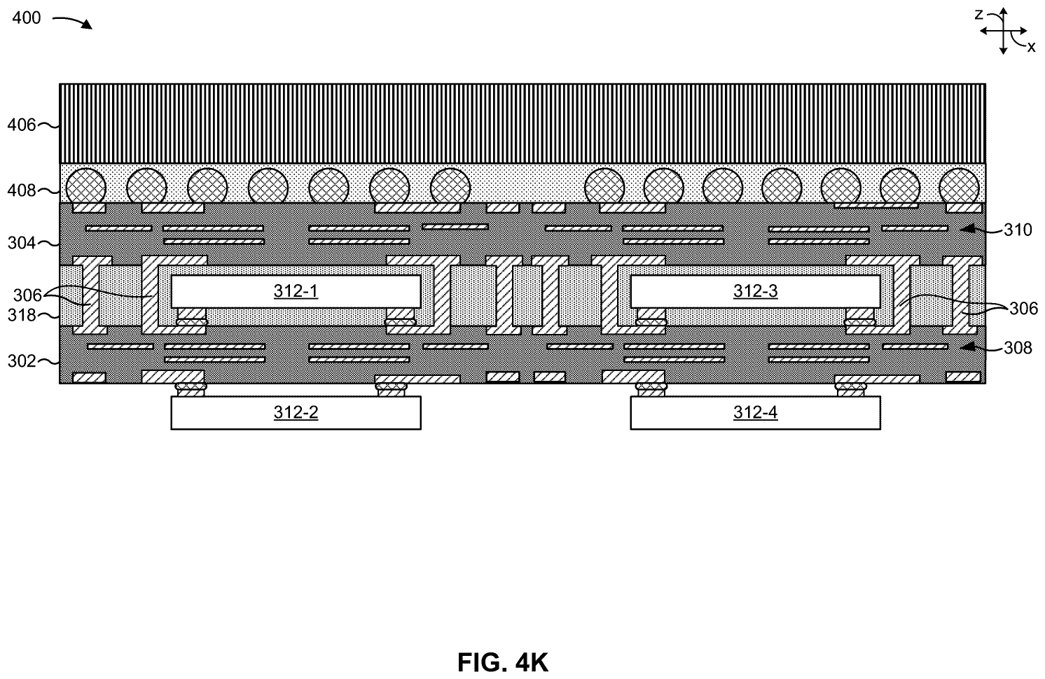

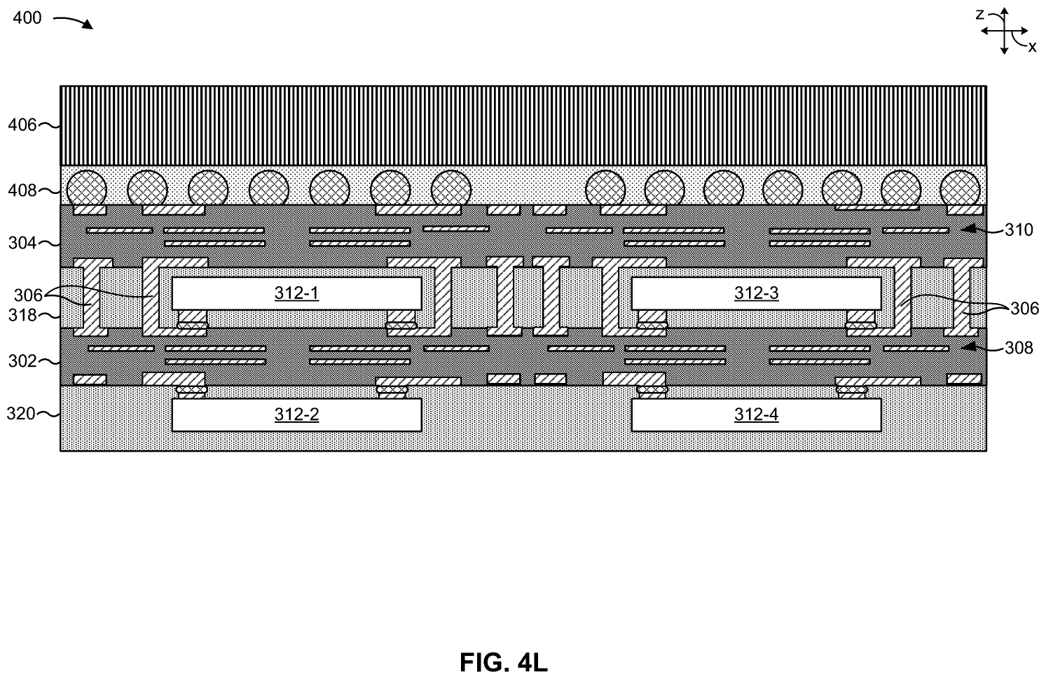

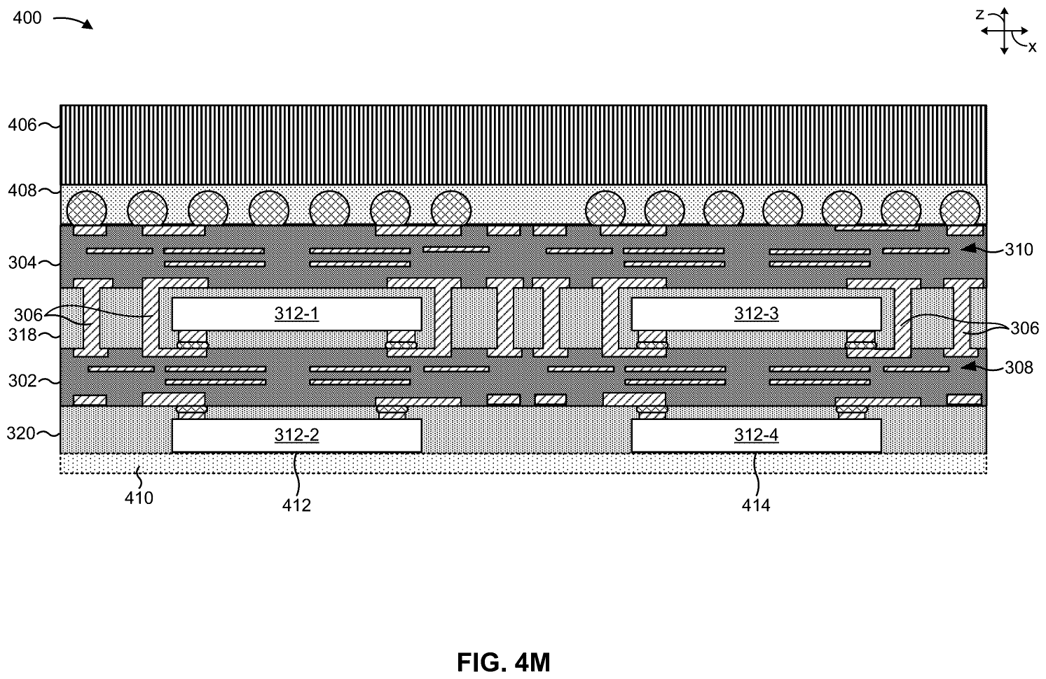

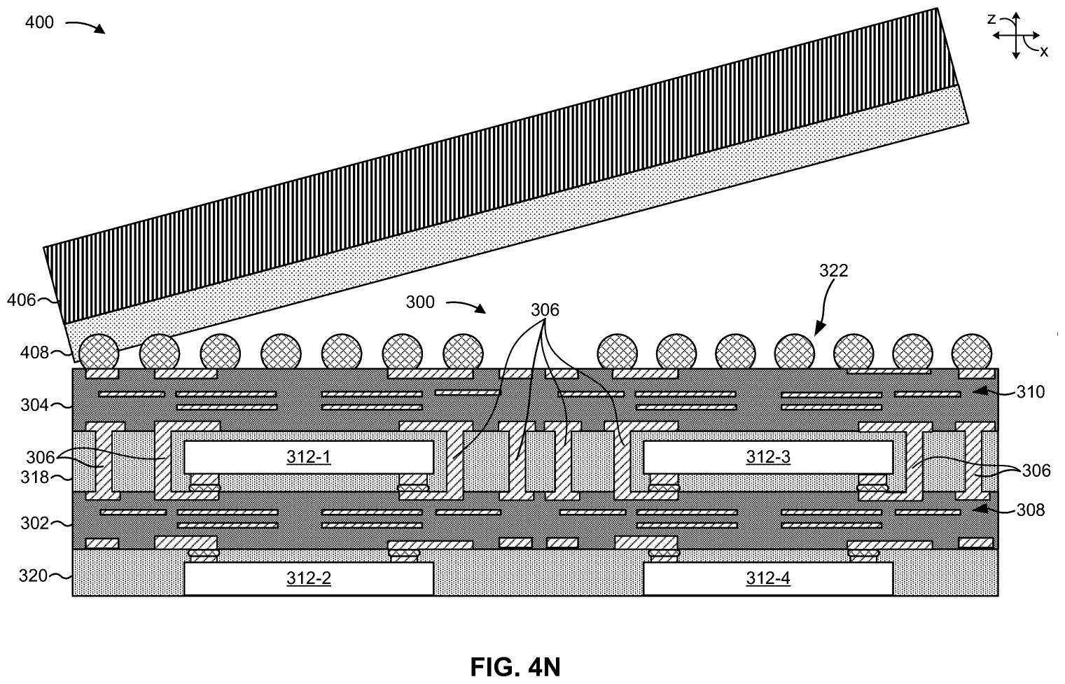

FIG. 3 is a diagram of an example semiconductor package 300 according to some implementations of the disclosure. More particularly, the example semiconductor package 300 may be a high performance semiconductor FOP (e.g., a high performance memory FOP, or a similar FOP). “FOP” may refer to a packaging process associated with connections (e.g., I/O connections or other electrical connections) “fanned-out” from a die and/or chip surface (e.g., via an RDL), thereby enabling more external I/O connections than are provided on organic-substrate-based packages, such as the semiconductor packages described above in connection with FIGS. 1 and 2. Additionally, or alternatively, in some implementations, FOP may refer to using a mold compound (e.g., an epoxy mold compound) to fully embed one or more chips and/or dies (e.g., a controller, memory dies, or similar dies) of an MCP memory device or similar semiconductor device, rather than attaching one or more dies on a substrate or an interposer. In some implementations, FOP may be referred to as a wafer-level packaging (WLP) technology and/or a panel-level packaging (PLP) technology, because certain RDLs may be built up at the wafer or package level, which is described in more detail below in connection with FIGS. 4A-4N.

As shown in FIG. 3, the semiconductor package 300 may include a first fan out RDL 302, a second fan out RDL 304, and a plurality of conducting through-package posts 306 (e.g., a plurality of copper pillars, copper interconnects, or similar posts) electrically coupling the first fan out RDL 302 and the second fan out RDL 304. In some implementations, each fan out RDL 302, 304 may include a plurality of electrical contacts, bond pads, traces, fingers, and/or similar electrical connections in order to provide electrical connectivity to other components of the semiconductor package 300. Accordingly, the plurality of conducting through-package posts 306 may electrically couple electrical connections of the first fan out RDL 302 with electrical connections of the second fan out RDL 304. More particularly, the first fan out RDL 302 may include a first plurality of electrical connections 308 (e.g., traces, pads, contacts, fingers, and/or similar electrical connections), and the second fan out RDL 304 may include a second plurality of electrical connections 310 (e.g., traces, pads, contacts, fingers, and/or similar electrical connections), with the plurality of conducting through-package posts 306 electrically coupling the first plurality of electrical connections 308 with the second plurality of electrical connections 310.

The semiconductor package 300 may further include multiple semiconductor dies 312. More particularly, as shown in FIG. 3, the semiconductor package 300 may include a first semiconductor die 312-1, a second semiconductor die 312-2, a third semiconductor die 312-3, and a fourth semiconductor die 312-4. The semiconductor dies 312 may be memory chips and/or dies (e.g., non-volatile memory 205 (e.g., NAND dies), volatile memory 210 (e.g., DRAM dies), or other memory dies), controllers, and/or similar semiconductor dies.

In some implementations, one or more semiconductor dies 312 may be electrically coupled to a first side of the first fan out RDL 302, and/or one or more semiconductor dies 312 may be electrically coupled to an opposing second side of the first fan out RDL 302. More particularly, in the example shown in FIG. 3, the first semiconductor die 312-1 and the third semiconductor die 312-3 are disposed on a first side (in the z-axis direction) of the first fan out RDL 302, with the first semiconductor die 312-1 and the third semiconductor die 312-3 being coupled to a first face of the first fan out RDL 302 (e.g., a face of the first fan out RDL 302 facing upward, in the z-axis direction, in the example shown in FIG. 3). Moreover, the second semiconductor die 312-2 and the fourth semiconductor die 312-4 are disposed on a second side (in the z-axis direction) of the first fan out RDL 302, with the second semiconductor die 312-2 and the fourth semiconductor die 312-4 being coupled to a second face of the first fan out RDL 302 (e.g., a face of the first fan out RDL 302 facing downward, in the z-axis direction, in the example shown in FIG. 3). In that regard, the first semiconductor die 312-1 and the third semiconductor die 312-3 may be disposed on an opposite side (in the z-axis direction) of the first fan out RDL 302 than the second semiconductor die 312-2 and/or the fourth semiconductor die 312-4.

Accordingly, in some implementations, a semiconductor die 312 may face an opposing semiconductor die 312, with the first fan out RDL 302 provided between the two semiconductor dies 312. More particularly, as shown in FIG. 3, the first semiconductor die 312-1 may face the second semiconductor die 312-2 with the first fan out RDL 302 provided between the first semiconductor die 312-1 and the second semiconductor die 312-2. Similarly, the third semiconductor die 312-3 may face the fourth semiconductor die 312-4 with the first fan out RDL 302 provided between the third semiconductor die 312-3 and the fourth semiconductor die 312-4.

In some implementations, each semiconductor die 312 may include a plurality of electrical contacts 314 that are electrically coupled to the first fan out RDL 302. More particularly, as best seen in the close-up view provided in the dashed line box in FIG. 3, a semiconductor die 312 may include a plurality of electrical contacts 314 that are electrically coupled to the first plurality of electrical connections 308 (e.g., bond pads provided on a surface of the first fan out RDL 302). In some implementations, the plurality of electrical contacts 314 may be coupled to the first plurality of electrical connections 308 via one or more solder bonds 316. In some implementations, the one or more solder bonds 316 may be associated with a solder paste, such as when the semiconductor die 312 is mounted to the first fan out RDL 302 using a surface mount (SMT) bonding technique. A solder paste may include a powdered solder material suspended in a flux paste. In such implementations, the tacky flux paste may hold the powdered solder material and/or the various components (e.g., the semiconductor die 312) in place until a soldering reflow process or similar soldering process melts the solder, thereby establishing an electrical connection between two terminals (e.g., in the example depicted in FIG. 3, one of the plurality of electrical contacts 314 of the semiconductor die 312 and a corresponding bond pad or similar electrical contact of the first fan out RDL 302). In some other implementations, the one or more solder bonds 316 may be associated with one or more solder bumps, such as one or more solder bumps deposited on a corresponding semiconductor die 312 during a semiconductor die 312 manufacturing process.

As further shown in FIG. 3, in some implementations, a face of a semiconductor die 312 including the plurality of electrical contacts 314 may face a similar face of an opposing semiconductor die 312, with the first fan out RDL 302 disposed between the facing dies 312. More particularly, in the depicted example, the first semiconductor die 312-1 includes a first plurality of electrical contacts 314, the second semiconductor die 312-2 includes a second plurality of electrical contacts 314, and the first semiconductor die 312-1 and the second semiconductor die 312-2 are electrically coupled to opposing sides of the first fan out RDL 302 such that first plurality of electrical contacts 314 faces the second plurality of electrical contacts 314 with the first fan out RDL 302 disposed between the first plurality of electrical contacts 314 and the second plurality of electrical contacts 314. Similarly, the third semiconductor die 312-3 includes a third plurality of electrical contacts 314, the fourth semiconductor die 312-2 includes a fourth plurality of electrical contacts 314, and the third semiconductor die 312-3 and the fourth semiconductor die 312-4 are electrically coupled to opposing sides of the first fan out RDL 302 such that third plurality of electrical contacts 314 faces the fourth plurality of electrical contacts 314 with the first fan out RDL 302 disposed between the third plurality of electrical contacts 314 and the fourth plurality of electrical contacts 314. In this way, the semiconductor dies 312 may be electrically coupled to the first fan out RDL 302 without the use of a TSV while maintaining a relatively small form factor (e.g., a chip size package).

In some implementations, the semiconductor dies 312 may be encased by a mold compound. More particularly, as shown in FIG. 3, the first semiconductor die 312-1 and the third semiconductor die 312-3 may be encased by a first mold compound 318 (e.g., a first mold layer), and the second semiconductor die 312-2 and the fourth semiconductor die 312-4 may be encased by a second mold compound 320 (e.g., a second mold layer). In some implementations, the plurality of conducting through-package posts 306 may extend through a mold compound, thereby electrically coupling components of the semiconductor package 300 (e.g., the first fan out RDL 302 and the second fan out RDL 304) to one another without the use of TSVs. More particularly, in the example shown in FIG. 3, the plurality of conducting through-package posts 306 may extend through the first mold compound 318, thereby electrically coupling the first fan out RDL 302 to the second fan out RDL 304. Moreover, in this implementation, the second mold compound 320 (e.g., the second mold layer) does not include conducting through-package posts 306, because no fan out RDL is built on the outer surface of the second mold compound 320. However, in some other implementations, additional fan out RDLs may be included in the semiconductor package 300, such as for purposes of including more semiconductor dies 312 for applications requiring higher density packages. In such implementations, a third fan out RDL may be included on the second mold compound 320 (e.g., on a lowermost, in the z-axis direction, surface of the second mold compound 320 in the orientation shown in FIG. 3), and thus conducting through-package posts 306 may be included in the second mold compound 320 in order to electrically couple the third fan out RDL to the first fan out RDL 302.

In some implementations, the semiconductor package 300 may include a plurality of solder bumps 322 (e.g., a plurality of solder balls), such as for purposes of coupling the semiconductor package 300 to a substrate of a larger system. More particularly, as shown in FIG. 3, the semiconductor package 300 may include the plurality of solder bumps 322 coupled to the second fan out RDL 304. In some implementations, the plurality of solder bumps 322 may be disposed on an opposite side, in the z-axis direction, of the second fan out RDL 304 than a side on which the first semiconductor die 312-1 and/or the third semiconductor die 312-3 are disposed. Put another way, the first semiconductor die 312-1 and/or the third semiconductor die 312-3 may be disposed on an inward facing side of the second fan out RDL 304, and the plurality of solder bumps 322 may be coupled to an opposing outward facing side of the second fan out RDL 304, as shown in FIG. 3.

In some implementations, the fan out semiconductor package 300 shown in FIG. 3 may exhibit performance and other improvements as compared to semiconductor packages employing TSVs, wire bonds, or other bonding techniques. For example, the semiconductor dies 312 (e.g., memory chips) may be attached to one or more fan out RDLs (e.g., the first fan out RDL 302 in the example shown in FIG. 3) that are formed either through a wafer-level or a panel-level build up process (as described in more detail below in connection with FIGS. 4A-4N), and/or each chip level of the semiconductor package 300 may be electrically connected via through-mold pillars, posts, or similar interconnects that may plated as part of the RDL process (as described in more detail below in connection with FIG. 4B). In this way, die density (e.g., memory density) may be scalable with each vertical level build up process eliminating high cost TSV structures while maintaining a small form factor package (e.g., a chip size package). Eliminating the use of TSV while maintaining a small form factor package may reduce fabrication costs associated with the semiconductor package 300 and/or may enable reduced conductor lengths as compared to conventional POP techniques. The structure of the semiconductor package 300 may further reduce timing delay and enhance signal integrity and power delivery for high-speed applications, which may be unachievable using wire bonding techniques. In that regard, the semiconductor package 300 may result in lower cost as compared to TSV packages, high-density scaling, high-speed performance, and high power delivery, while enabling a small form factor package (e.g., chip size package).

As indicated above, FIG. 3 is provided as an example. Other examples may differ from what is described with respect to FIG. 3.

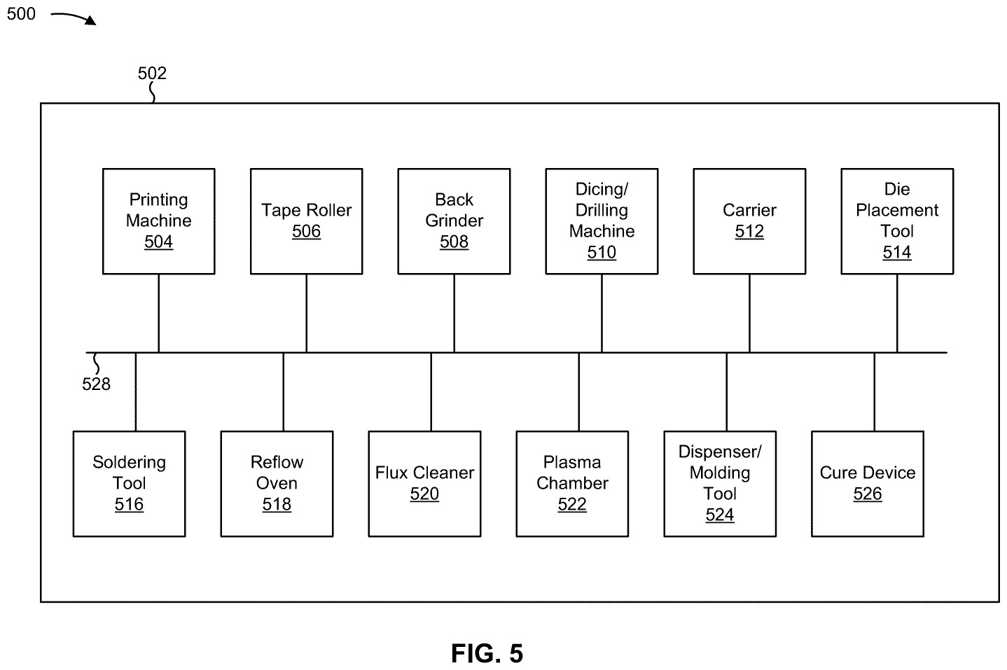

FIGS. 4A-4N are diagrams of an example process 400 used to fabricate a semiconductor FOP. More particularly, FIGS. 4A-4N are diagrams of an example process 400 that may be used to fabricate the semiconductor package 300 described above in connection with FIG. 3. The fabrication process 400 shown and described in connection with FIGS. 4A-4N may be performed using various semiconductor manufacturing equipment, such as the semiconductor manufacturing equipment described below in connection with FIG. 5.

As shown in FIG. 4A, the process 400 may include receiving a first carrier 402. In some implementations, the first carrier 402 may be a wafer-shaped carrier (e.g., in wafer-based fabrication processes), a panel-shaped carrier (e.g., in panel-based fabrication processes), a strip-shaped carrier (e.g., in strip-based fabrication processes), or a similar carrier. The first carrier 402 may be constructed from any suitable material used in a semiconductor package manufacturing process. In some implementations, the first carrier 402 may be a glass carrier, which may aid in a laser-debonding process. In some implementations, the first carrier 402 may include (e.g., may be laminated or coated with) a first release layer 404, sometimes referred to as a sacrificial layer. The first release layer 404 may aid during a debonding process (e.g., a laser-debonding process or another debonding process) by permitting the first carrier 402 to be easily removed from a semiconductor package after package formation, which is described in more detail below in connection with FIG. 4I.

In some implementations, the process 400 may be referred to as an RDL-first FOP process, because an RDL (e.g., the first fan out RDL 302) is first built on the first carrier 402 and/or the first release layer 404, with the remaining components (e.g., dies, mold compounds, or similar components) then built up, in the z-axis direction, on top of the RDL. In this regard, the first carrier 402 and/or the first release layer 404 may be prepared for forming an RDL thereon. This may include performing certain RDL preparation steps, such as a polyimide patterning process, a seed layer deposition process, a photoresist coating process, or a similar preparation step.

As shown in FIG. 4B, the process may include building up a fan out RDL, pillars, and/or pads over first carrier 402 and/or the first release layer 404. For example, the process 400 may include forming the first fan out RDL 302 on the first carrier 402 (more particularly, on the first release layer 404 of the first carrier 402). As described above in connection with FIG. 3, the first fan out RDL 302 may include a first plurality of electrical connections 308 (e.g., electrical traces, pads, interconnects, fingers, or similar electrical connections), and thus the process may include forming and/or plating the first plurality of electrical connections 308 in a dielectric or similar material. Put another way, the process 400 may include forming a dielectric layer including conducting traces within the dielectric layer. Additionally, or alternatively, the process 400 may include forming and/or plating a plurality of pillars (e.g., the plurality of conducting through-package posts 306) extending away from a first face of the first fan out RDL 302 (e.g., an upward facing face of the first fan out RDL 302 in the example shown in FIG. 4B).

More particularly, electrical connections, such as signal traces, bond pads, wire-bond fingers, or similar connections (e.g., the first plurality of electrical connections 308, the plurality of conducting through-package posts 306, or similar electrical connections) may be integrally formed in the first fan out RDL 302 (e.g., may be integrally formed within the dielectric of the first fan out RDL 302) for purposes of bonding the first fan out RDL 302 to one or more other components of the semiconductor package 300 (e.g., the second fan out RDL 304, one or more semiconductor dies 312, or similar components), and/or for purposes of conducting electricity (e.g., signals) throughout the first fan out RDL 302 and/or throughout the semiconductor package 300. In some implementations, forming the first fan out RDL 302 on the first carrier 402 and/or the first release layer 404 may include forming a metal (e.g., copper) based RDL and/or forming a metal (e.g., copper) based pad layer. More particularly, the first fan out RDL 302 may be formed on the first carrier 402 and/or the first release layer 404 via a metal (e.g., copper) plating process, a photoresist strip process, a seed layer etching process, or a similar process.

As shown by FIGS. 4C and 4D, the process 400 may include bonding one or more semiconductor dies 312 to a first face of the first fan out RDL 302, such that the one or more semiconductor dies 312 are electrically coupled to the first plurality of electrical connections 308 of the first fan out RDL 302. More particularly, as shown in FIGS. 4C and 4D, the process 400 may include bonding the first semiconductor die 312-1 and the third semiconductor die 312-3 to the first face of the first fan out RDL 302 (e.g., an upward facing face, in the z-axis direction) using the solder bonds 316. In some implementations, the solder bonds 316 may be associated with a solder paste. In some other implementations, the solder bonds 316 may be associated with bump bonds (e.g., solder bump bonds, pillar bump bonds, and/or other bump bonds). In some implementations, the semiconductor dies 312 may be flip-chip dies manufactured with multiple bumps (e.g., solder bumps or balls, pillar bumps, or similar bumps) facing upward, in the z-axis direction, and then flipped during the chip attachment process shown in FIGS. 4C and 4D such that the bumps face the first fan out RDL 302 and are bonded thereto. The solder bonds 316 may be formed using a reflow process, a thermal compression bonding (TCB) process, or a similar process.

As shown in FIG. 4E, the process 400 may include encasing one or more semiconductor dies 312 and the plurality of conducting through-package posts 306 in the first mold compound 318. More particularly, the process 400 may include encasing the first semiconductor die 312-1, the third semiconductor die 312-3, and/or the plurality of conducting through-package posts 306 in the first mold compound 318. In some implementations, encasing the first semiconductor die 312-1, the third semiconductor die 312-3, and/or the plurality of conducting through-package posts 306 in the first mold compound 318 may be associated with a compression molding process (sometimes referred to as a wafer-level compression molding process and/or a panel-level compression molding process). In some implementations, the compression molding process may result in overmolding, in which the first mold compound 318 extends higher, in the z-axis direction, than is otherwise desired for the semiconductor package 300 (e.g., the first mold compound 318 may extend beyond upper surfaces of the plurality of conducting through-package posts 306 and/or may extend beyond certain design specifications). In such implementations, additional mold processing steps may be performed, such as back-grinding, through-package post revealing, or a similar process, which is described in more detail below in connection with FIG. 4M.

As shown in FIG. 4F, in some implementations, another fan out RDL may be formed over the first mold compound 318. More particularly, the process 400 may include forming the second fan out RDL 304 on the first mold compound 318. In some implementations, the second fan out RDL 304 may be formed using a substantially similar process as the process described above in connection with forming the first fan out RDL 302. More particularly, in a similar manner as described above in connection with FIG. 4B, forming the second fan out RDL 304 may include forming a metal (e.g., copper) based RDL and/or forming a metal (e.g., copper) based pad layer. For example, a first layer may be formed on the first mold compound 318 using a metal (e.g., copper) plating process, a photoresist strip process, a seed layer etching process, or other similar processes. Subsequent layers may be formed by repeating the processes (e.g., the metal (e.g., copper) plating process, the photoresist strip process, the seed layer etching process, or other similar processes) multiple times to create a multilayer RDL.

In some implementations, the second fan out RDL 304 may include the second plurality of electrical connections 310 (e.g., traces, pads, interconnects, fingers, or similar electrical connections). In such implementations, the second fan out RDL 304, and more particularly the second plurality of electrical connections 310 of the second fan out RDL 304, may be electrically coupled to the first plurality of electrical connections 308 via the plurality of conducting through-package posts 306, as shown in FIG. 4F. Moreover, in some implementations, the second plurality of electrical connections 310 may include pads or similar electrical contacts used for purposes of electrically coupling the semiconductor package 300 to a substrate (e.g., a PCB) of a higher level system. More particularly, in some implementations, forming the second fan out RDL 304 may include forming copper pads or similar electrical contacts on an outward facing face of the second fan out RDL 304 (e.g., an upward facing, in the z-axis direction, face of the second fan out RDL 304, as shown in FIG. 4F), which may be used for purposes of electrically coupling the semiconductor package 300 to a substrate, PCB, or similar component of a higher level system.

As shown in FIG. 4G, the process 400 may include forming the plurality of solder bumps 322 (e.g., solder balls) on the second fan out RDL 304. In some implementations, the plurality of solder bumps 322 may be soldered (e.g., attached and reflowed) to the second fan out RDL 304 for purposes of providing electrical connectivity to a PCB or similar structure of a higher level system. In some implementations, attaching the plurality of solder bumps 322 to the second fan out RDL 304 may be referred to as wafer-level solder ball attachment and reflow and/or panel-level solder ball attachment and reflow.

As shown in FIG. 4H, the process 400 may include bonding a second carrier 406 (which may include a second release layer 408) to the second fan out RDL 304. More particularly, the process 400 may include bonding the second carrier 406 and/or the second release layer 408 the second fan out RDL 304 over the plurality of solder bumps 322. The second carrier 406 may be used to support the semiconductor package 300 during subsequent die attachment and/or molding steps, as described in more detail below in connection with FIGS. 4I-4N.

As shown in FIG. 4I, the process 400 may include debonding the first carrier 402 from the first fan out RDL 302. In some implementations, a debonding process (sometimes referred to as a wafer-level debonding process and/or a panel-level debonding process) may be used to debond the first carrier 402 from the first fan out RDL 302. In some implementations, the first carrier 402 and/or the first release layer 404 may be removed from the first fan out RDL 302 via a laser debonding process. In some implementations, removing the first carrier 402 and/or the first release layer 404 from the first fan out RDL 302 may include cleaning a bottom (in the z-axis direction) surface of the first fan out RDL 302 in order to remove residual adhesives, portions of the first release layer 404 (e.g., portions of the sacrificial layer), or similar contaminants following removal of the first carrier 402.

As shown in FIGS. 4J and 4K, the process 400 may include bonding one or more semiconductor dies 312 to a second face of the first fan out RDL 302 (e.g., a face of the first fan out RDL 302 that faces away from the face of the first fan out RDL 302 to which the first semiconductor die 312-1 and/or the third semiconductor die 312-3 are attached), such that the semiconductor dies 312 are electrically coupled to the first plurality of electrical connections 308 of the first fan out RDL 302. More particularly, as shown in FIGS. 4J and 4K, the process 400 may include bonding the second semiconductor die 312-2 and the fourth semiconductor die 312-4 to the second face of the first fan out RDL 302 (e.g., a downward facing face, in the z-axis direction, of the first fan out RDL 302) using the solder bonds 316 (e.g., solder paste, solder bumps, or similar solder bonds, as described above in connection with FIGS. 4C and 4D).

As shown in FIG. 4L, the process 400 may include encasing the second semiconductor die 312-2 and/or the fourth semiconductor die 312-4 in the second mold compound 320. In some implementations, encasing the second semiconductor die 312-2 and/or the fourth semiconductor die 312-4 in the second mold compound 320 may be associated with a compression molding process (e.g., a wafer-level compression molding process and/or a panel-level compression molding process). In some implementations, the compression molding process may result in overmolding, in which the second mold compound 320 extends lower, in the z-axis direction, than is otherwise desired for the semiconductor package 300 (e.g., the second mold compound 320 may extend beyond certain design specifications). In such implementations, additional mold processing steps may be performed, such as back-grinding, through-package post revealing, or a similar process.

More particularly, as shown in FIG. 4M, the process 400 may include grinding the second mold compound 320 to remove a portion 410 of the second mold compound 320. In some implementations, removing the portion 410 of the second mold compound 320 may be performed for purposes of exposing a surface 412 of the second semiconductor die 312-2 and/or exposing a surface 414 of the fourth semiconductor die 312-4. Exposing the surface 412 of the second semiconductor die 312-1 and/or the surface 414 of the fourth semiconductor die 312-4 may improve heat dissipation and/or a thermal performance of the second semiconductor die 312-2 and/or the fourth semiconductor die 312-4 by exposing the second semiconductor die 312-2 and/or the fourth semiconductor die 312-4 to a surrounding environment when the semiconductor package 300 is mounted to a substrate (e.g., PCB) of a higher level system.

As shown in FIG. 4N, the process 400 may include debonding the second carrier 406 from the second fan out RDL 304, resulting in the completed semiconductor package 300. More particularly, in a similar manner as described above in connection with the first carrier 402 in FIG. 4I, the second carrier 406 and/or the second release layer 408 may be removed from the second fan out RDL 304 via a laser debonding process. In some implementations, removing the second carrier 406 and/or the second release layer 408 from the second fan out RDL 304 may include cleaning a top (in the z-axis direction) surface of the second fan out RDL 302 in order to remove residual adhesives, portions of the second release layer 408 (e.g., portions of the sacrificial layer), or similar contaminants after removing the second carrier 406.

As indicated above, FIGS. 4A-4N are provided as an example. Other examples may differ from what is described with respect to FIGS. 4A-4N.

FIG. 5 is a diagram of example equipment 500 used to manufacture various semiconductor packages, semiconductor dies, memory devices, or similar components described herein. In some implementations, the equipment 500 may be used to manufacture the semiconductor package 300. As shown in FIG. 5, the equipment 500 may include a packaging system 502. The packaging system 502 may include one or more devices or tooling, such as a printing machine 504, a tape roller 506, a back grinder 508, a dicing and/or drilling machine 510, a carrier 512, a die placement tool 514, a soldering tool 516, a reflow oven 518, a flux cleaner 520, a plasma chamber 522, a dispenser and/or molding tool 524, and/or a cure device 526. One or more devices may be may physically or communicatively coupled to one another. For example, one or more devices may interconnect via wired connections and/or wireless connections, such as via a bus 528. Additionally, or alternatively, one or more devices may form part of an electronics assembly manufacturing line.

The printing machine 504 may be a device capable of printing patterns in a material such as silicon, a dielectric material, a polyimide layer, or a similar material, for purposes of forming an integrated circuit, an RDL, or the like. In some implementations, the printing machine 504 may be a lithography device capable of printing patterns in a material to form an integrated circuit.

The tape roller 506 may be a device capable of laminating a tape (e.g., a back grinding tape) on a semiconductor wafer and/or a semiconductor die. The tape roller 506 may be capable of applying pressure to a tape as the tape is being laminated onto a wafer or a die.

The back grinder 508 may be a device capable of grinding a backside of a semiconductor wafer, a semiconductor die, and/or a semiconductor device assembly, thereby reducing a thickness of the wafer, die, and/or semiconductor device assembly to a desired thickness (e.g., as described above in connection with FIG. 4M). In some implementations, the back grinder 508 may be associated with a rotary table, a chuck table, and/or a grinding wheel for purposes of grinding a wafer, a die, and/or an assembly to a suitable thickness.

The dicing and/or drilling machine 510 may be a device capable of dicing a die, such as a microcontroller, a memory die, or other semiconductor die, from a wafer. In some implementations, the dicing and/or drilling machine 510 may include one or more dicing blades and/or one or more lasers to dice a die from the wafer. In some implementations, the dicing and/or drilling machine 510 may be a device capable of drilling through vias in a mold compound. For example, the dicing and/or drilling machine 510 may include a laser capable of drilling through vias in a mold compound.

The carrier 512 may be a device capable of supporting and/or carrying a substrate during a die and/or chip attachment process, during a compression molding process, or during a similar process. The carrier 512 may be constructed from a non-contaminating material, such as quartz, glass, or a similar material, and may be capable of withstanding high temperatures. In that regard, the carrier 512 may be capable of carrying a substrate and/or one or more die through one or more ovens, such as a reflow oven 518 and/or a cure device 526.

The die placement tool 514 may be a high-precision tool capable of placing a die onto a substrate, an RDL, or similar mounting surface. In some implementations, the die placement tool 514 may be capable of flipping a flip chip die during a placement process, such that an active surface of the flip chip die, which may be facing up during preliminary manufacturing steps, may face the substrate during the flip chip die placement process. In some implementations, the die placement tool 514 may include one or more sensors capable of aligning bump bonds on a die with bond pads on a substrate during a flip chip die attachment process. In some implementations, the die placement tool may be configured to place a die attach component between a die a substrate, such as a die attach film (DAF) that couples the die to the substrate.

The soldering tool 516 may be capable of forming one or more solder connections between components of a semiconductor package. For example, the soldering tool 516 may be capable of forming wire bond connections between components of a semiconductor package by soldering wires connecting wire bond pads from one component to wire bond pads of another component. In some examples, the soldering tool 516 may be capable of applying a solder paste to between electrical contacts of electronic components, such as between electrical contacts provided on a semiconductor component and corresponding electrical contacts provided on a substrate and/or an RDL. Additionally, or alternatively, the soldering tool 516 may be capable of applying solder or other electrically conductive material to form a portion of an electrical connection to be formed between a die and a substrate. For example, the soldering tool 516 may be capable of applying a grid of solder bumps (e.g., micro balls) to a die and/or a molded die assembly, which will align with a grid of bump pads on a substrate during a flip chip attachment process, or the like.

The reflow oven 518 may be a device capable of heating components to a suitable temperature to cause a reflow of solder or other bonding material, thereby causing the solder or similar material to melt and make an electrical connection between two components.

The flux cleaner 520 may be a device capable of removing residual flux from a soldering process. In some implementations, the flux cleaner 520 may include a heater capable of removing residual flux through a heat treatment process. Additionally, or alternatively, the flux cleaner 520 may include a nozzle or similar device capable of applying a cleaning agent to a component in order to remove residual flux therefrom.

The plasma chamber 522 may be a device capable of providing plasma treatment to a component. In some implementations, the plasma chamber 522 may be capable of directly or indirectly applying a plasma stream to an area of a component, such as for purposes of preparing the area on the component for receiving an epoxy underfill, or the like.

The dispenser and/or molding tool 524 may be a device capable of dispensing a filler material around a die or similar component. In some implementations, the dispenser and/or molding tool 524 may be capable of dispensing a mold compound (e.g., an epoxy mold compound) during a compression molding process. In some implementations, the dispenser and/or molding tool 524 may include a dispensing needle capable of applying an epoxy underfill by capillary action under pressure, such as by dispensing underfill material around a periphery of a die and/or other electrical component such that the underfill material flows beneath the die and/or other electrical component and fills a space between the die and/or other electrical component and a substrate.

The cure device 526 may be a device capable of curing a material, such as an ultraviolet (UV) curable adhesive layer, a mold compound, such as an epoxy mold compound, an epoxy underfill material, a moldable underfill (MUF) material, or a similar material. In some implementations, the cure device 526 may include a UV lamp capable of irradiating a back grinding tape with UV light in order to cure an adhesive layer thereof. In some implementations, the cure device 526 may be an oven configured to heat a mold compound to a suitable curing temperature. Additionally, or alternatively, the cure device 526 may be capable of curing a mold compound via a chemical reaction, by the application of UV light, by the application of other radiation, or the like.

The number and arrangement of devices and networks shown in FIG. 5 are provided as an example. In practice, there may be additional devices, fewer devices, different devices, or differently arranged devices than those shown in FIG. 5. Furthermore, two or more devices shown in FIG. 5 may be implemented within a single device, or a single device shown in FIG. 5 may be implemented as multiple, distributed devices. Additionally, or alternatively, a set of devices (e.g., one or more devices) of equipment 500 may perform one or more functions described as being performed by another set of devices of equipment 500.

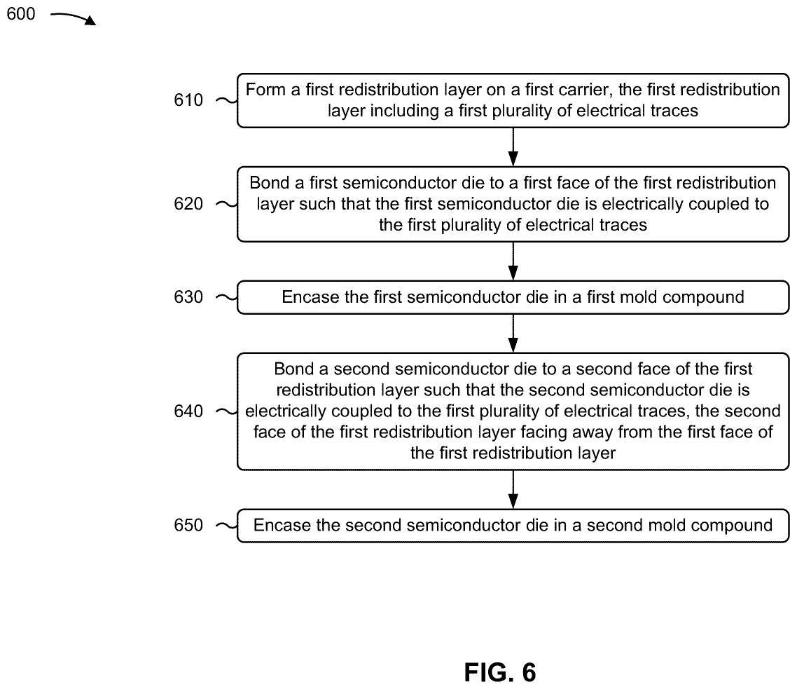

FIG. 6 is a flowchart of an example method 600 of forming a high performance integrated assembly or memory device having fan out packaging. In some implementations, one or more process blocks of FIG. 6 may be performed by various semiconductor manufacturing equipment, such as the semiconductor manufacturing equipment described above in connection with FIG. 5.

As shown in FIG. 6, the method 600 may include forming a first redistribution layer on a first carrier, the first redistribution layer including a first plurality of electrical traces (block 610). As further shown in FIG. 6, the method 600 may include bonding a first semiconductor die to a first face of the first redistribution layer such that the first semiconductor die is electrically coupled to the first plurality of electrical traces (block 620). As further shown in FIG. 6, the method 600 may include encasing the first semiconductor die in a first mold compound (block 630). As further shown in FIG. 6, the method 600 may include bonding a second semiconductor die to a second face of the first redistribution layer such that the second semiconductor die is electrically coupled to the first plurality of electrical traces, the second face of the first redistribution layer facing away from the first face of the first redistribution layer (block 640). As further shown in FIG. 6, the method 600 may include encasing the second semiconductor die in a second mold compound (block 650).

The method 600 may include additional aspects, such as any single aspect or any combination of aspects described below and/or in connection with one or more other methods described elsewhere herein.

In a first aspect, the first redistribution layer includes a plurality of pillars extending away from the first face of the first redistribution layer, the method further comprising forming a second redistribution layer on the first mold compound, the second redistribution layer including a second plurality of electrical traces electrically coupled to the first plurality of electrical traces via the plurality of pillars.

In a second aspect, alone or in combination with the first aspect, the method 600 includes bonding a second carrier to second redistribution layer, and debonding the first carrier from the first redistribution layer.

In a third aspect, alone or in combination with one or more of the first and second aspects, the method 600 includes forming a plurality of solder bumps on the second redistribution layer, wherein the second carrier is bonded to the second redistribution layer over the plurality of solder bumps.

In a fourth aspect, alone or in combination with one or more of the first through third aspects, the method 600 includes, after encasing the second semiconductor die in a second mold compound, debonding the second carrier from the second redistribution layer.

In a fifth aspect, alone or in combination with one or more of the first through fourth aspects, the method 600 includes grinding the second mold compound to expose a surface of the second semiconductor die.

Although FIG. 6 shows example blocks of the method 600, in some implementations, the method 600 may include additional blocks, fewer blocks, different blocks, or differently arranged blocks than those depicted in FIG. 6. In some implementations, the method 600 may include forming the semiconductor package 300, an integrated assembly that includes the semiconductor package 300, any part described herein of the semiconductor package 300, and/or any part described herein of an integrated assembly that includes the semiconductor package 300. For example, the method 600 may include forming one or more of the parts 302-322.

In some implementations, a semiconductor device assembly includes a first fan out redistribution layer; a first semiconductor die disposed on a first side, in a direction, of the first fan out redistribution layer and coupled to a first face of the first fan out redistribution layer; and a second semiconductor die disposed on a second side, in the direction, of the first fan out redistribution layer, different from the first side, and coupled to a second face of the first fan out redistribution layer, different from the first face.

In some implementations, a semiconductor package includes a first redistribution layer; and a plurality of semiconductor dies electrically coupled to the first redistribution layer without use of through silicon vias, the plurality of semiconductor dies including: a first semiconductor die including a first plurality of electrical contacts, wherein the first semiconductor die is electrically coupled to a first side of the first redistribution layer; and a second semiconductor die including a second plurality of electrical contacts, wherein the second semiconductor die is electrically coupled to an opposing second side of the first redistribution layer such that first plurality of electrical contacts faces the second plurality of electrical contacts with the first redistribution layer disposed between the first plurality of electrical contacts and the second plurality of electrical contacts.

In some implementations, a method includes forming a first redistribution layer on a first carrier, the first redistribution layer including a first plurality of electrical traces; bonding a first semiconductor die to a first face of the first redistribution layer such that the first semiconductor die is electrically coupled to the first plurality of electrical traces; encasing the first semiconductor die in a first mold compound; bonding a second semiconductor die to a second face of the first redistribution layer such that the second semiconductor die is electrically coupled to the first plurality of electrical traces, wherein the second face of the first redistribution layer faces away from the first face of the first redistribution layer; and encasing the second semiconductor die in a second mold compound.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings. As used herein, the term “substantially” means “within reasonable tolerances of manufacturing and measurement.”

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a first fan out redistribution layer;
a first semiconductor die disposed on a first side, in a direction, of the first fan out redistribution layer and coupled to a first face of the first fan out redistribution layer; and
a second semiconductor die disposed on a second side, in the direction, of the first fan out redistribution layer, different from the first side, and coupled to a second face of the first fan out redistribution layer, different from the first face.

2. The semiconductor device assembly of claim 1, further comprising a second fan out redistribution layer, wherein the second fan out redistribution layer is disposed on an opposite side, in the direction, of the first semiconductor die than a side on which the first fan out redistribution layer is disposed.

3. The semiconductor device assembly of claim 2, wherein the first fan out redistribution layer is electrically coupled to the second fan out redistribution layer via a plurality of conducting through-package posts.

4. The semiconductor device assembly of claim 3, wherein the first semiconductor die is encased by a mold compound, and wherein the plurality of conducting through-package posts extend through the mold compound.

5. The semiconductor device assembly of claim 2, further comprising a plurality of solder bumps coupled to the second fan out redistribution layer, wherein the plurality of solder bumps is disposed on an opposite side, in the direction, of the second fan out redistribution layer than a side on which the first semiconductor die is disposed.

6. The semiconductor device assembly of claim 1, wherein the first semiconductor die and the second semiconductor die are electrically coupled to the first fan out redistribution layer without use of a through silicon via.

7. The semiconductor device assembly of claim 1, wherein the first semiconductor die is encased by a first mold layer, and wherein the second semiconductor die is encased by a second mold layer different from the first mold layer.

8. The semiconductor device assembly of claim 7, further comprising a second fan out redistribution layer, wherein the first fan out redistribution layer is electrically coupled to the second fan out redistribution layer via a plurality of conducting through-package posts disposed in the first mold layer, and wherein the second mold layer does not include conducting through-package posts.

9. A semiconductor package, comprising:
a first redistribution layer; and
a plurality of semiconductor dies electrically coupled to the first redistribution layer without use of through silicon vias, the plurality of semiconductor dies including:
a first semiconductor die including a first plurality of electrical contacts, wherein the first semiconductor die is electrically coupled to a first side of the first redistribution layer; and
a second semiconductor die including a second plurality of electrical contacts, wherein the second semiconductor die is electrically coupled to an opposing second side of the first redistribution layer such that first plurality of electrical contacts faces the second plurality of electrical contacts with the first redistribution layer disposed between the first plurality of electrical contacts and the second plurality of electrical contacts.

10. The semiconductor package of claim 9, further comprising a second redistribution layer, wherein the first semiconductor die is disposed between, in a direction, the first redistribution layer and the second redistribution layer.

11. The semiconductor package of claim 10, wherein the first redistribution layer is electrically coupled to the second redistribution layer via a plurality of conducting through-package posts.

12. The semiconductor package of claim 11, wherein the first semiconductor die is encased by a mold compound, and wherein the plurality of conducting through-package posts extend through the mold compound.

13. The semiconductor package of claim 10, further comprising a plurality of solder bumps coupled to the second redistribution layer, wherein the plurality of solder bumps is disposed on an opposite side, in the direction, of the second redistribution layer than a side on which the first semiconductor die is disposed.

14. The semiconductor package of claim 9, wherein the first semiconductor die is encased by a first mold layer, and wherein the second semiconductor die is encased by a second mold layer different from the first mold layer.

15. A method, comprising:
forming a first redistribution layer on a first carrier, the first redistribution layer including a first plurality of electrical traces;
bonding a first semiconductor die to a first face of the first redistribution layer such that the first semiconductor die is electrically coupled to the first plurality of electrical traces;
encasing the first semiconductor die in a first mold compound;
bonding a second semiconductor die to a second face of the first redistribution layer such that the second semiconductor die is electrically coupled to the first plurality of electrical traces, the second face of the first redistribution layer facing away from the first face of the first redistribution layer; and
encasing the second semiconductor die in a second mold compound.

16. The method of claim 15, wherein the first redistribution layer includes a plurality of pillars extending away from the first face of the first redistribution layer, the method further comprising:
forming a second redistribution layer on the first mold compound, the second redistribution layer including a second plurality of electrical traces electrically coupled to the first plurality of electrical traces via the plurality of pillars.

17. The method of claim 15, further comprising, prior to bonding the second semiconductor die to the second face of the first redistribution layer:
bonding a second carrier to second redistribution layer; and
debonding the first carrier from the first redistribution layer.

18. The method of claim 17, further comprising forming a plurality of solder bumps on the second redistribution layer, wherein the second carrier is bonded to the second redistribution layer over the plurality of solder bumps.

19. The method of claim 17, further comprising, after encasing the second semiconductor die in a second mold compound, debonding the second carrier from the second redistribution layer.

20. The method of claim 15, further comprising grinding the second mold compound to expose a surface of the second semiconductor die.
